(19) United States
(12) Patent Application Publication
(10) Pub. No.: US 2018/0336996 A1
(43) Pub. Date: Nov. 22, 2018

(54) ELECTRONIC CONTROL UNIT

(71) Applicant: MANDO CORPORATION, Gyeonggi-do (KR)

(72) Inventor: Hans Joerg FEIGEL, Seoul (KR)

(73) Assignee: MANDO CORPORATION, Gyeonggi-do (KR)

(21) Appl. No.: 15/980,740

(22) Filed: May 16, 2018

(30) Foreign Application Priority Data
May 16, 2017 (KR) 10-2017-0060380

(51) Int. Cl. H01F 38/14; H05K 1/14

(52) U.S. Cl. CPC H01F 38/14; H05K 1/144; H01R 12/52; H05K 2201/1003; H05K 2201/042; H05K 2201/10189

(57) ABSTRACT

Disclosed is an electronic control unit including a first printed circuit board (PCB) configured to receive power from a first terminal power supplier; and a second PCB configured to receive power from a second terminal power supplier, wherein the first PCB and the second PCB are electrically connected with at least one double winding coil, the first PCB is electrically connected to a first coil of a first double winding coil, and the second PCB is electrically connected to a second coil of the first double winding coil. According to embodiments of the present disclosure, a smaller ECU may be manufactured by connecting a plurality of PCBs with a double winding coil, and the stability of the ECU may be secured by having an extra double winding coil.

### CROSS-REFERENCE TO RELATED APPLICATION

This application is based on and claims priority under 35 U.S.C. § 119 to Korean Patent Application No. 10-2017-0060380 filed on May 16, 2017, in the Korean Intellectual Property Office, the disclosure of which is incorporated herein by reference in its entirety.

### BACKGROUND

### 1. Field of the Invention

The present disclosure relates to an electronic control unit, and more particularly, to a structure for facilitating connection between a plurality of printed circuit boards installed in an electronic control unit.

### 2. Discussion of Related Art

In modern society, vehicles are the most common transportation means, and people using the vehicles are ever increasing. Development of auto technologies is changing a lot of things in our lives, e.g., making it easy to travel a long distance and making our lives more convenient.

An electric power steering (EPS) system is to improve vehicle fuel efficiency and cope actively with electric vehicles by driving the motor through electronic control based on driving speed of the vehicle such that light steering torque is produced for the steering wheel in case of parking or slowdown and heavy steering torque is produced in case of high-speed driving in order to provide the driver with high-speed driving stability.

The EPS system brings some benefits to reducing the weight of the vehicle, preventing power loss and accordingly improving the fuel efficiency (by 3 to 5%), and in addition, to reducing the maintenance expenses and having eco-friendly properties.

Other benefits of the EPS system are reducing the number of parts therein, thereby making it light and improving assemblability, enabling accurate steering torque control for each speed condition of the vehicle, thereby improving high-speed driving stability and steering performance.

To control the EPS system, the vehicle is equipped with an electronic control unit (ECU) having at least one printed circuit board (PCB), and the size of the ECU tends to become smaller to avoid interference with other electronic devices installed in the vehicle.

It is common to provide two PCBs in a single ECU to make the ECU small, but with existing technologies, stability issues have made it impossible to make the ECU small.

### SUMMARY OF THE INVENTION

To solve the aforementioned problem that the conventional technologies have, the present disclosure provides a smaller electronic control unit (ECU) manufactured by efficiently arranging a plurality of printed circuit boards (PCBs) in a single ECU.

In accordance with an aspect of the present disclosure, an electronic control unit (ECU) is provided. The ECU includes a first printed circuit board (PCB), and a second PCB arranged above and in parallel with the first PCB, wherein the first PCB and the second PCB are electrically connected with at least one double winding coil, the first PCB may be electrically connected to a first coil of a first double winding coil, and the second PCB may be electrically connected to a second coil of the first double winding coil.

The first PCB may be electrically connected to a first coil of a second double winding coil, and the second PCB may be electrically connected to a second coil of the second double winding coil.

The first PCB may be electrically connected to the first coil through a first connection pin, and the second PCB may be electrically connected to the second coil through a second connection pin.

The second connection pin may be electrically connected to the second PCB by penetrating the first PCB.

The second connection pin may be physically separated from the first PCB.

In accordance with another aspect of the present disclosure, an electronic control unit (ECU) is provided. The ECU includes a first printed circuit board (PCB), and a second PCB arranged above and in parallel with the first PCB, wherein the first PCB is electrically connected to at least one double winding coil, and the second PCB is connected to the first PCB through a connector.

The connector may include a communication bus line.

The connector may include an optical or magnetic coupling device.

In accordance with another aspect of the present disclosure, an electronic control unit (ECU) is provided. The ECU includes a first printed circuit board (PCB), a second PCB arranged above and in parallel with the first PCB, and a third PCB arranged below and in parallel with the first PCB, wherein the third PCB is electrically connected to at least one double winding coil, and the first and second PCBs are electrically connected to the third PCB.

The ECU may further include an internal cover arranged between the first and second PCBs to cover the first PCB to prevent the surface of the first PCB from being exposed to the outside.

The ECU may further include an internal cover arranged between the second and third PCBs to cover the third PCB to prevent the surface of the third PCB from being exposed to the outside.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a perspective view of an electronic control unit (ECU), according to an embodiment of the present disclosure;

FIG. 2 is a perspective view of an ECU, according to another embodiment of the present disclosure;

FIG. 3 is a perspective view of an ECU, according to another embodiment of the present disclosure;

FIG. 4 is a perspective view of an ECU, according to another embodiment of the present disclosure;

FIG. 5 is a perspective view of an ECU, according to another embodiment of the present disclosure; and

FIG. 6 is a perspective view of an ECU, according to another embodiment of the present disclosure.

### DETAILED DESCRIPTION OF EXEMPLARY EMBODIMENTS

Embodiments and features as described and illustrated in the present disclosure are only preferred examples, and various modifications thereof may also fall within the scope of the disclosure.

The terminology used herein is for the purpose of describing particular embodiments only and is not intended to limit the present disclosure. It is to be understood that the singular forms “a,” “an,” and “the” include plural references unless the context clearly dictates otherwise.

It will be further understood that the terms “include”, “comprise” and/or “have” when used in this specification, specify the presence of stated features, integers, steps, operations, elements, and/or components, but do not preclude the presence or addition of one or more other features, integers, steps, operations, elements, components, and/or groups thereof. It will be understood that, although the terms first, second, third, etc., may be used herein to describe various elements, components, regions, layers and/or sections, these elements, components, regions, layers and/or sections should not be limited by these terms.

Embodiments of the present disclosure will now be described in detail with reference to accompanying drawings to be readily practiced by an ordinary skill in the art. It should be noted that what is irrelative to the present disclosure is omitted from the drawings.

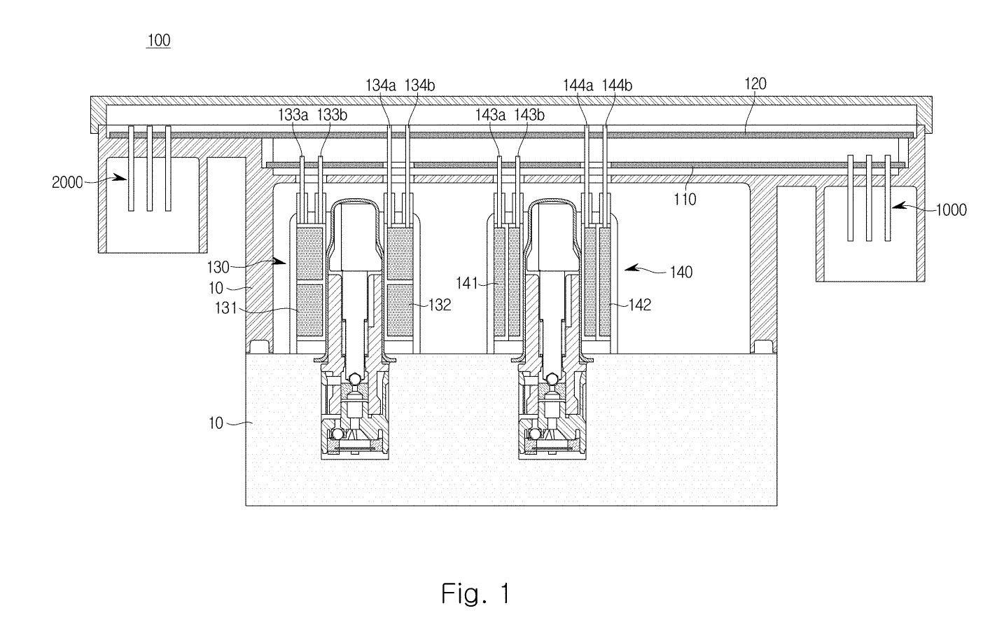

FIG. 1 is a perspective view of an electronic control unit (ECU), according to an embodiment of the present disclosure.

Referring to FIG. 1, an ECU 100 includes at least one power supply terminal. Specifically, the ECU 100 may include a first terminal 1000 to supply power to a first printed circuit board (PCB) 110, and a second terminal 2000 to supply power to a second PCB 120.

The ECU 100 may also include a housing 10 that forms the entire exterior of the ECU 100, and a base 20 on which the plurality of PCBs 110 and 120 and a plurality of double winding coils 130 and 140 may be located.

The first PCB 110 and the second PCB 120 may be arranged in parallel, and may include various diodes, memories or devices depending on the purpose of the brake system.

The first PCB 110 may be electrically connected to a first coil 131 of the first double winding coil 130 and a first coil 141 of the second double winding coil 140, and the second PCB 120 may be electrically connected to a second coil 132 of the first double winding coil 130 and a second coil 142 of the second double winding coil 140.

Specifically, the first double winding coil 130 includes the first coil 131 and the second coil 132 having a plurality of solenoid coils, and the second double winding coil 140 includes the first coil 141 and the second coil 142 having a plurality of solenoid coils. The first coils 131 and 141 are electrically connected to the first PCB 110 through first connection pins 133 and 143, and the second coils 132 and 142 are electrically connected to the second PCB 120 through second connection pins 134 and 144.

The first connection pins 133 and 143 and the second connection pins 134 and 144 are connected to the PCBs 110 and 120, respectively, in the form of being inserted thereto, making it possible for the first coil 131 of the first double winding coil 130 to be electrically connected to the first PCB 110 and for the second coil 132 of the first double winding coil 130 to be electrically connected to the second PCB 120.

The second connection pins 134 and 144 may be electrically connected to the second PCB 120 by penetrating the first PCB 110, and may be arranged in such a form that may penetrate the first PCB 110 in a state of being physically separated from the first PCB 110.

In the present disclosure, a single double winding coil 130 is connected to the two PCBs 110 and 120 in the housing 10 as shown in FIG. 1, which facilitates more economical manufacturing of the ECU 100.

Furthermore, since the ECU 100 includes an extra double winding coil 140, even if one of the two double winding coils 130 and 140 is broken, the other may take over the job of the broken one and thus the ECU may be driven more stably.

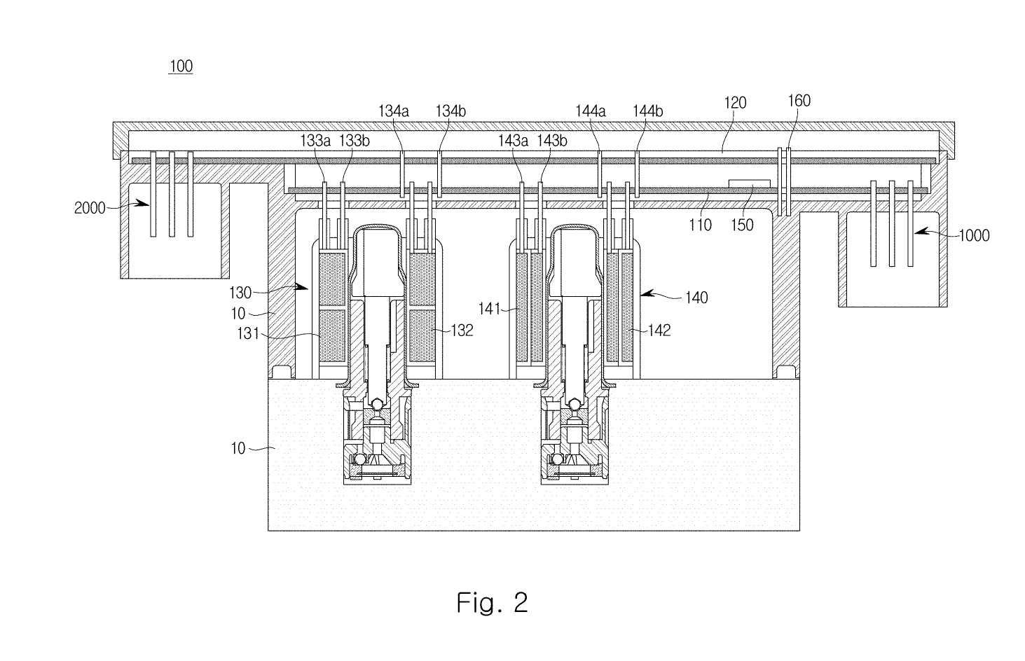

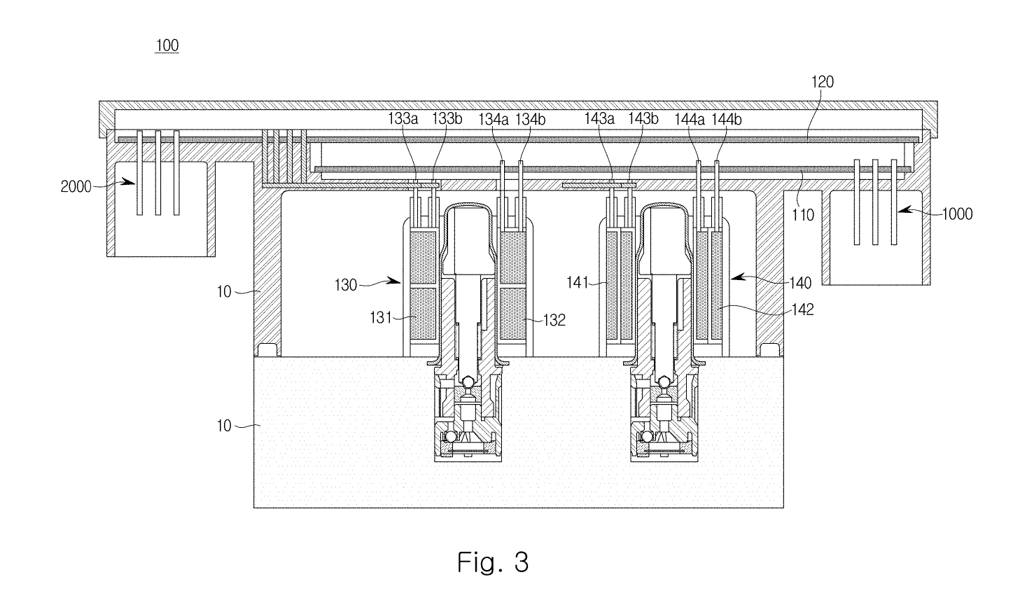

FIGS. 2 and 3 are perspective views of ECUs, according to other embodiments of the present disclosure.

The basic structure of the ECU 100 as shown in FIG. 2 is the same as the ECU 100 shown in FIG. 1, except for the way of connection between the second PCB 120 and the second coil 132 of the first double winding coil 130.

Specifically, for the ECU 100 shown in FIG. 2, the connection pin 134 of the first double winding coil 130 and the connection pin 144 of the second double winding coil 140 are not directly connected to the second PCB 120 but are connected to the first PCB 110.

Accordingly, the second PCB 120 may be electrically connected to the first and second double winding coils 130 and 140 through the first PCB 110, and the first PCB 110 and the second PCB 120 may be connected through third connection pins 136 and 146.

The third connection pin 136 and 146 may include a communication bus line, and the first and second PCBs 110 and 120 may communicate with each other through an optical device 150 or a magnetic coupling device 150 equipped in the ECU 100.

As shown in FIG. 3, the second PCB 120 may be connected to the first connection pin 133 in a press-fit connection method.

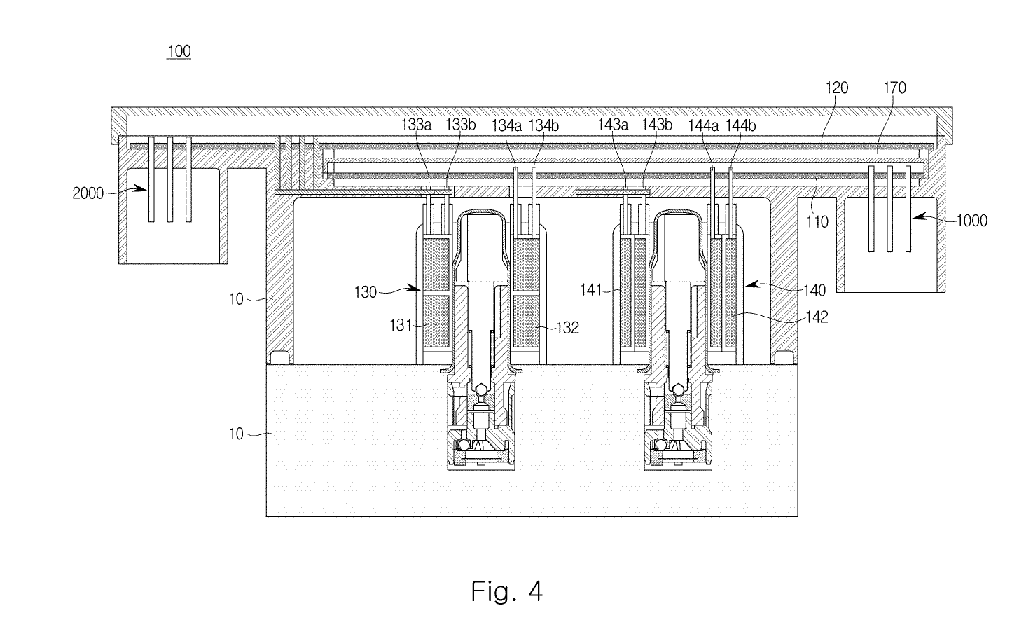

FIG. 4 is a perspective view of the ECU 100, according to another embodiment of the present disclosure.

Referring to FIG. 4, the ECU 100 has the same basic structure as that of the ECU 100 shown in FIG. 3 except that the ECU 100 shown in FIG. 4 further includes an internal cover 170 located between the first and second PCBs 110 and 120.

The internal cover 170 of the ECU 100 shown in FIG. 4 may prevent the PCBs 110 and 120 from being damaged by incoming materials from the outside environment.

Furthermore, since the first and second PCBs 110 and 120 are physically separated, even if one of them is damaged, the other PCB may remain stable.

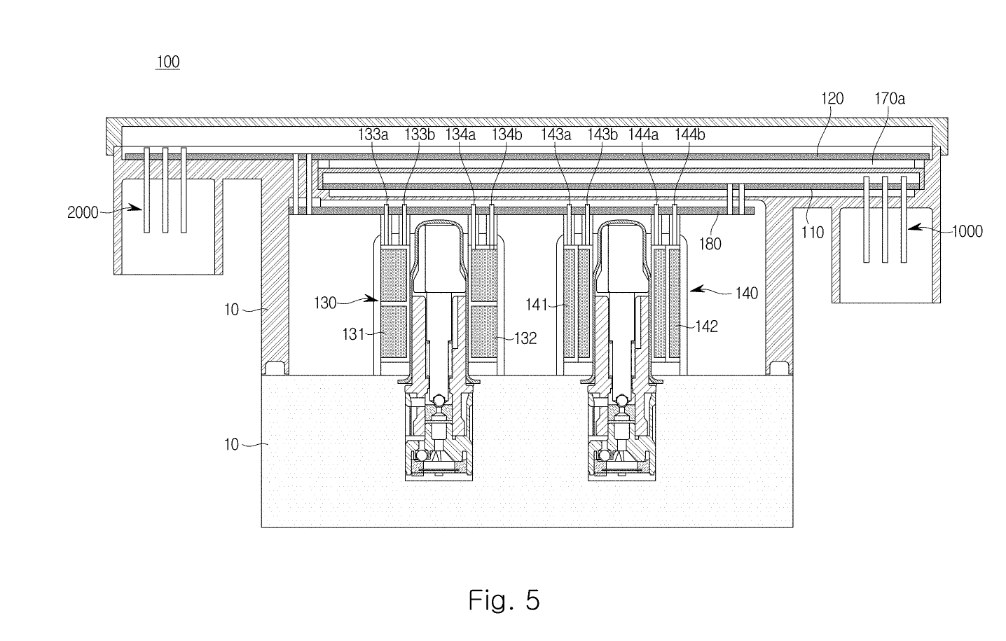

FIG. 5 is a perspective view of the ECU 100, according to another embodiment of the present disclosure.

Referring to FIG. 5, the ECU 100 includes a third PCB 180 arranged under the first and second PCBs 110 and 120, and the first and second PCBs 110 and 120 are electrically connected via the third PCB 170 without being directly connected to the double winding coils 130 and 140.

Specifically, the third PCB 180 is electrically connected to the first connection pins 133 and 143 and the second connection pins 134 and 144 and connected to the first and second PCBs 110 and 120 in the press-fit connection method, so the first and second PCBs 110 and 120 may make mutual communication with the double winding coil 130 and the second double winding coil 140.

Furthermore, as shown in FIG. 5, an internal cover 170a is arranged between the first and second PCBs 110 and 120, to prevent incoming dust or water from the outside. Alternatively, the internal cover 170a may be arranged between the second and third PCBs 120 and 180.

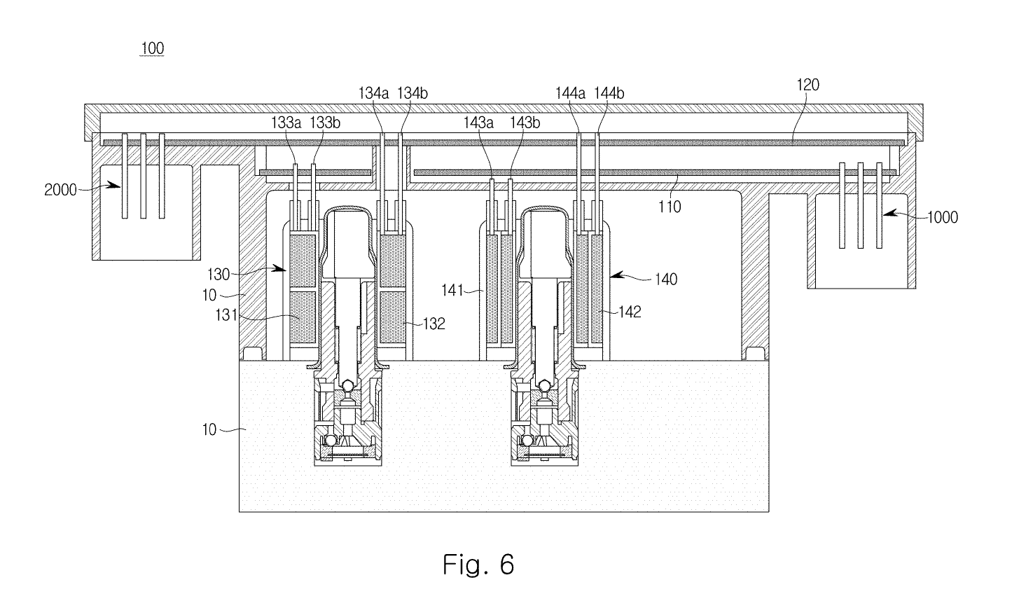

FIG. 6 is a perspective view of the ECU 100, according to another embodiment of the present disclosure.

In this embodiment, the connection pins 133, 134, 143, and 144 of the double winding coils 130 and 140 may be connected to the third PCB 180, which may be connected to the first and second PCBs 110 and 120 in the press-fit connection method, and an internal cover 160 may be arranged between the first and second PCBs 110 and 120.

Features and effects of embodiments of the present disclosure have been described with reference to accompanying drawings.

According to embodiments of the present disclosure, a smaller ECU may be manufactured by connecting two PCBs using a double winding coil, and the stability of the ECU may be secured by having an extra double winding coil.

Although the present disclosure is described with reference to some embodiments as described above and accompanying drawings, it will be apparent to those ordinary skilled in the art that various modifications and changes can be made to the embodiments. For example, the aforementioned method may be performed in different order, and/or the aforementioned systems, structures, devices, circuits, etc., may be combined in different combinations from what is described above, and/or replaced or substituted by other components or equivalents thereof, to obtain appropriate results. Therefore, other embodiments and equivalents thereof may fall within the following claims.

What is claimed is:

1. An electronic control unit (ECU) comprising:
a first printed circuit board (PCB) configured to receive power from a first terminal power supplier; and
a second PCB configured to receive power from a second terminal power supplier, wherein the first PCB and the second PCB are electrically connected with at least one double winding coil,
the first PCB is electrically connected to a first coil of a first double winding coil, and the second PCB is electrically connected to a second coil of the first double winding coil.

2. The ECU of claim 1, wherein the first PCB is electrically connected to a first coil of a second double winding coil, and the second PCB is electrically connected to a second coil of the second double winding coil.

3. The ECU of claim 1, wherein the first PCB is electrically connected to the first coil through a first connection pin, and the second PCB is electrically connected to the second coil through a second connection pin.

4. The ECU of claim 3, wherein the second connection pin is electrically connected to the second PCB by penetrating the first PCB.

5. The ECU of claim 4, wherein the second connection pin is physically separated from the first PCB.

6. An electronic control unit (ECU) comprising:
a first printed circuit board (PCB) configured to receive power from a first terminal power supplier; and
a second PCB configured to receive power from a second terminal power supplier,
wherein the first PCB is electrically connected to at least one double winding coil, and the second PCB is connected to the first PCB through a connector.

7. The ECU of claim 6, wherein the connector comprises a communication bus line.

8. The ECU of claim 6, wherein the connector comprises an optical or magnetic coupling device.

9. The ECU of claim 6, further comprising: a third PCB electrically connected to the at least one double winding coil,
wherein the first and second PCBs are electrically connected to the third PCB.

10. The ECU of claim 9, further comprising: an internal cover arranged between the first and second PCBs to cover the first PCB to prevent the surface of the first PCB from being exposed to the outside.

11. The ECU of claim 9, further comprising: an internal cover arranged between the second and third PCBs to cover the third PCB to prevent the surface of the third PCB from being exposed to the outside.
